(19) United States
(12) Patent Application Publication
(10) Pub. No.: US 2021/0387238 A1
(43) Pub. Date: Dec. 16, 2021

(54) APPARATUS FOR REMOVING PARTICLES USING SYMMETRICAL GAS INJECTION

(71) Applicant: Jin Ho KIM, Suwon-si, Gyeonggi-do (KR)

(72) Inventor: Jin Ho KIM, Suwon-si, Gyeonggi-do (KR)

(21) Appl. No.: 17/290,955

(22) PCT Filed: Oct. 24, 2019
(86) PCT No.: PCT/KR2019/014062

§ 371 Date: May 3, 2021

(30) Foreign Application Priority Data
Nov. 23, 2018 (KR) 10-2018-0146303

(51) Int. Cl. B08B 5/02; B08B 15/04; B08B 13/00; B01D 46/54

(52) U.S. Cl. CPC B08B 5/02; B01D 46/543; B08B 13/00; B08B 15/04

(57) ABSTRACT

The present invention provides an apparatus for removing particles using symmetrical gas injection, the apparatus comprising: a casing having an inner space; a gas injection part in which a plurality of gas nozzles are formed on one side of the casing, the plurality of gas nozzles are disposed symmetrically and away from an object, and particles on the surface of the object are removed by means of injecting gas on the object; and a recovery part which has a recovery pipe inserted therein and connected to the other side of the casing and is for recovering, via the recovery pipe, the particles which have been removed from the object. According to the present invention, the gas nozzles inject in symmetrical directions and thus diffusion of particles removed from the surface of the object is prevented, the object is not contaminated, and the particles can accurately be recovered, detected and counted.

### TECHNICAL FIELD

The present invention relates to an apparatus for removing particles, and more particularly, to an apparatus for removing particles using symmetrical gas injection for effectively removing and recovering particles from the surface of an object in a clean room and the like.

### BACKGROUND ART

In general, with the advancement of the industry, in a production site as well as an office environment, a need to control particles such as dust has increased, and a clean room was introduced to maintain the production site in a clean state to prevent adverse effects of the particles on a product.

Such a clean room is introduced and operating in industry and science laboratories such as semiconductors, displays, pharmacies, hospitals, etc. In particular, in a high-tech industry including nano-scale and high-precise processes such as a manufacturing process of a semiconductor or an LCD display, since microenvironmental conditions at sites where products are manufactured may also greatly affect the quality of the products, the cleanliness required in the clean room tends to be gradually increasing. For example, in the semiconductor manufacturing process, pattern defects caused by depositing particles oscillated from an automated device or the like on a wafer surface have been pointed out as a major cause of yield reduction of the products.

As such, when particles are present at the site of manufacturing the products in a high-tech industry, the particles may be reversed to the products during the manufacturing process to cause fatal product defects. These particles are accumulated in ceilings, walls, and floors in the site of manufacturing the products, production and measurement facilities, and various resources and also attached to worker's clothing. In addition, since the movement of airflow is caused according to movement of robots, workers, and products and the imbalance of spatial temperature, particles which have been accumulated on the surfaces of workers, objects, or adjacent portions thereof are reversed to contaminate the products, resulting in product defects.

As the related arts for removing particles, in U.S. Pat. No. 5,253,538 (issued on Oct. 19, 1993), there is disclosed a device for counting particles on a surface by a vacuum suction method in which when a sample surface is suctioned by an air pump through a scanner, the particles are filtered through a laser diode light source counter and a filter.

However, since an ability of separating particles from the sample surface is deteriorated by suctioning the particles by the vacuum suction method, recently, there is a problem that microparticles of several μm or less required in semiconductor and display industries cannot be removed.

Further, in Korean Patent Publication No. 10-2008-0017768 (published on Feb. 27, 2008), there is disclosed an apparatus for removing particles by a gas spraying method including a substrate transfer device on which a substrate is placed, a gas spray unit which sprays gas on the substrate transfer device while being inclined at a predetermined angle to remove particles attached on the substrate, and a suction unit which faces the gas spray unit on the substrate transfer device and suctions the particles removed from the substrate while being inclined at a predetermined angle.

However, the particles removed from the substrate are spread around by airflow of the sprayed gas so that the contamination occurs. Even after the spraying is completed, the particles are attached to another position of the substrate while transferring by the airflow again, so that re-contamination may occur. In addition, there is a problem that it is difficult to accurately recover, detect and count the particles, and there is a risk that a worker inhales the particles during an operation.

### DISCLOSURE

### Technical Problem

The present invention is derived to solve all the aforementioned problems, and an object of the present invention is to provide an apparatus for removing particles using symmetrical gas injection in which gas nozzles inject in symmetrical directions to prevent diffusion of particles removed from the surface of an object, the object is not contaminated, and the particles are able to be accurately recovered, detected and counted.

### Technical Solution

In order to solve the objects, the present invention provides an apparatus for removing particles using symmetrical gas injection, the apparatus comprising: a casing having an inner space; a gas injection part in which a plurality of gas nozzles are formed on one side of the casing, the plurality of gas nozzles are disposed symmetrically and away from an object, and particles on the surface of the object are removed by injecting gas on the object; and a recovery part which has a recovery pipe connected to the other side of the casing and inserted therein and recovers the particles removed from the object to the recovery pipe.

### Advantageous Effects

According to the present invention, there is an effect that the gas nozzles inject in symmetrical directions to prevent diffusion of particles removed from the surface of an object, the object is not contaminated, and the particles are able to be accurately recovered, detected and counted.

Further, there is an effect that even when the vacuum is not formed in the recovery part, the particles are able to be transferred to a predetermined distance and recovered, and even if imbalance occurs on a pressure or injection amount of the injection gas injected in the symmetrical directions or the injection gas are irregularly diffused after colliding depending on various shapes of the surface of the object, the particles are able to be induced in a desired direction and recovered.

Further, there is an effect that the particles are able to be more accurately detected and counted by injecting cleaning gas to prevent foreign substances from being introduced to the recovery part, automatic control is enabled by setting injection time and injection intervals depending on the surface shape of the object, and the particles are able to be smoothly collected and recovered.

### DESCRIPTION OF DRAWINGS

FIG. 1 is a diagram illustrating an apparatus for removing particles and auxiliary facilities according to an embodiment of the present invention.

FIG. 2 is a perspective view illustrating an apparatus for removing particles according to an embodiment of the present invention.

FIGS. 3A to 3D are plan views illustrating arrangements of gas nozzles according to an embodiment of the present invention and FIG. 3E is a side view.

FIG. 4 is a diagram illustrating a recovery operation of particles removed from the surface of an object according to an embodiment of the present invention.

FIG. 5 is a schematic view of further comprising a second recovery part according to an embodiment of the present invention.

### MODES FOR THE INVENTION

Hereinafter, detailed contents for implementing an apparatus for removing particles using symmetrical gas injection according to the present invention will be described based on embodiments with reference to the accompanying drawings.

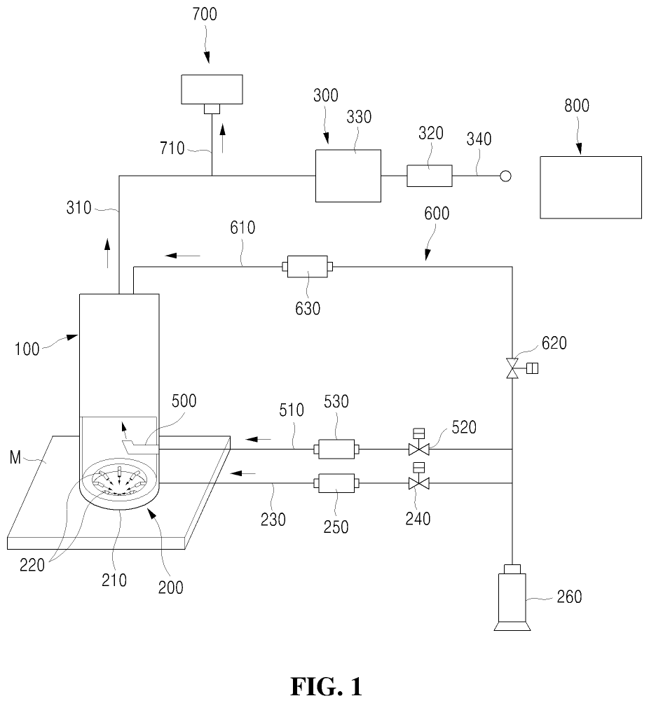

An apparatus for removing particles using symmetrical gas injection according to the present invention is to effectively remove and recover particles from the surface of an object in a clean room and the like. Referring to FIG. 1, the apparatus for removing particles may include a casing 100, a gas injection part 200, and a recovery part 300 and selectively further include a second recovery part 400, a direction induction nozzle 500, a gas injection part 600, a particle detection part 700, and a control part 800.

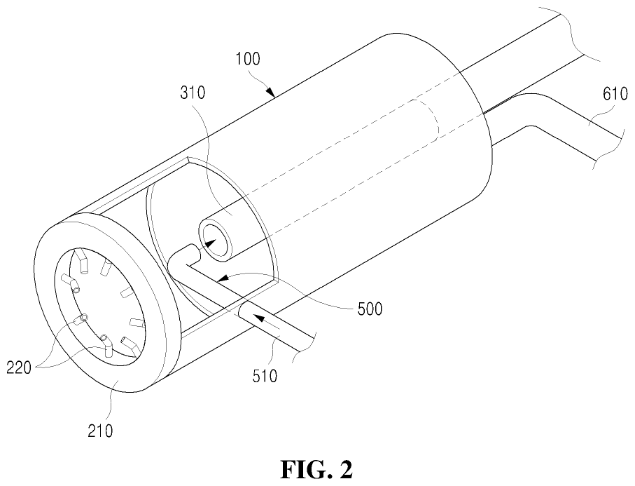

Referring to FIG. 2, the casing 100 has an inner space, may be provided in a vertical or horizontal direction, and provides a space in which particles P removed from the surface of the object are induced to the recovery part 300.

The gas injection part 200 has a nozzle block 210 formed at one side of the casing 100, the nozzle block 210 has a ring or strip shape in which a central portion penetrates so that the surface of an object M is exposed to gas nozzles 220, and the object M may be seated and supported on a support.

The nozzle block 210 may have a shape such as a circular ring or a quadrangular ring, but is not particularly limited to the shape.

The nozzle block 210 is connected to a gas supply pipe 230 to distribute gas supplied from the gas supply pipe 230 to a plurality of gas nozzles 220 through the nozzle block 210. The gas supply pipe 230 is connected to an air compressor 260 to receive compressed gas and an opening/closing valve 240 that is automatically controlled to be opened and closed by the control part 800, and an air filter 250 are provided.

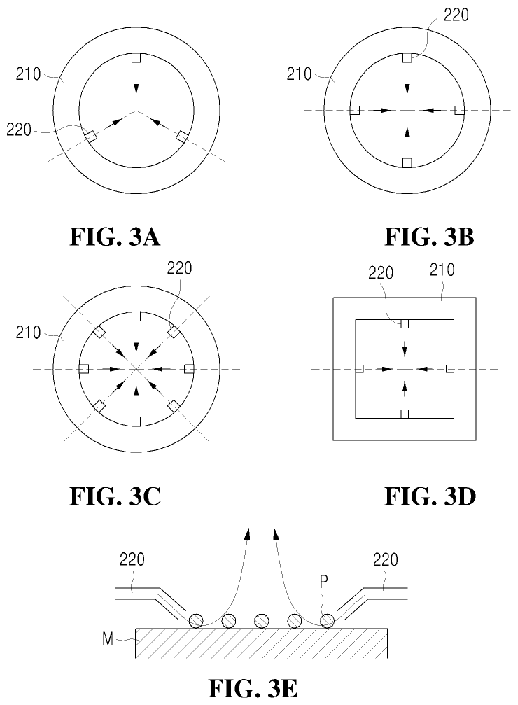

Referring to FIG. 3A-3E, the plurality of gas nozzles 220 is provided along the nozzle block 210, wherein the plurality of gas nozzles 220 are provided to be symmetrical to each other and inclined at a predetermined angle toward the object M to be spaced apart from the object M, and the particles P attached to the surface of the object M are removed by injecting the gas to the object M.

Generally, the symmetry includes point symmetry, line symmetry, plane symmetry, etc., and elements of the symmetry include a symmetrical center, a symmetrical axis, and a symmetrical plane. The symmetrical center refers to a point where a line connected through the symmetrical center is divided into equal parts by the symmetrical center, the symmetrical axis refers to an axis which has the same shape two or more times when rotating the object at 360° on an axis of one vertical line, and includes a 2-fold symmetrical axis, a 3-fold symmetrical axis, a 4-fold symmetrical axis, a 8-fold symmetrical axis, etc. The symmetrical plane refers to a plane that two half parts of the object have the same shape based on a mirror surface.

For example, two gas nozzles may also be provided in the nozzle block 210 to be symmetrical to each other. Three gas nozzles 220 illustrated in FIG. 3A are provided in the nozzle block 210 to be symmetrical to each other by a 3-fold symmetrical axis and four gas nozzles 220 illustrated in FIG. 3B are provided in the nozzle block 210 to be symmetrical to each other by a 4-fold symmetrical axis. FIG. 3C illustrates that four gas nozzles 220 are provided in the nozzle block 210 to be symmetrical to each other by a 8-fold symmetrical axis, and FIG. 3D illustrates that the nozzle block is formed in a quadrangular ring shape and four gas nozzles 220 are disposed to be symmetrical to each other by a 4-fold symmetrical axis. FIG. 3E is a side view illustrating the arrangement and operation of the gas nozzles disposed to be symmetrical to each other as described above.

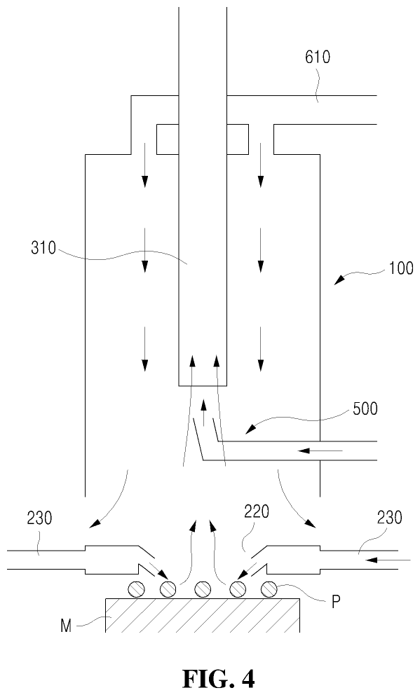

The gas nozzles 220 disposed to be symmetrical to each other as described above inject the same amount of gas toward the object M at a predetermined angle with the same pressure. Referring to FIG. 4, the symmetrically injected gas collides with the surface of the object M to remove the particles P from the object M and then ascends upward from the central portion of the nozzle block 210 together with the particles P removed by colliding with each other. As such, the particles removed from the surface of the object M by the gas injected in symmetrical directions to each other are prevented from being diffused around, the contamination of the object M does not occur, and the particles are induced to the recovery part 300 to be able to be accurately recovered, detected, and counted.

In the recovery part 300, a recovery pipe 310 is connected to the other side of the casing 100, that is, an opposite side of the nozzle block 210, a part of the recovery pipe 310 is inserted into the casing 100, and a recovery port corresponding to a pipe inlet is formed at an end of the recovery pipe. At this time, the recovery port may also be formed so that the diameter is gradually increased toward the end, and the particles P removed from the object M by the gas symmetrically injected from the gas nozzles 220 are recovered on a passage of the recovery pipe 310 through the recovery port.

The recovery pipe 310 is connected to a vacuum pump 330 to suction the particles P by a vacuum suction method and discharge the particles P through a discharge pipe 340, and a membrane filter 320 is provided on the recovery passage of the recovery pipe 310 to collect the recovered particles P. Further, a particle collector such as the membrane filter 320 is provided in the recovery pipe 310 to collect the particles P, thereby confirming the contamination and the degree thereof.

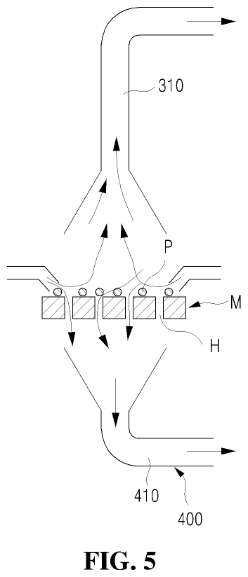

Referring to FIG. 5, if a hole is formed in the object M, the second recovery part 40 is additionally provided even on a back side of the object M to recover the particles P removed from the object M together with the gas through a second recovery pipe 410 by the gas symmetrically injected from the gas nozzles 220, thereby preventing the particles removed from the surface of the object M and the gas passing through the hole from being diffused around. At this time, a recovery port corresponding to the pipe inlet is formed at the end of the second recovery pipe 410, wherein the recovery port may also be formed so that the diameter is gradually increased toward the end.

The direction induction nozzle 500 is connected to a direction induction pipe 510 and formed in the middle of the casing 100 and serves to induce the particles P removed from the object M in a desired direction by injecting direction induced gas toward the recovery pipe 310 of the recovery part 300. At this time, the direction induction pipe 510 is connected with the air compressor 260 to receive compressed gas and an opening/closing valve 520 that is automatically controlled to be opened and closed by the control part 800, and an air filter 530 are provided.

The direction induction nozzle 500 induces the particles P removed from the object M to the recovery pipe 310 by injecting the direction induced gas toward the inlet of the recovery pipe 310 even when the vacuum is not formed in the recovery pipe 310 to transmit and recover the particles by a predetermined distance. Even if imbalance occurs on a pressure or injection amount of the gas injected in the symmetrical directions of the gas nozzles 220 or the injected gas is irregularly diffused after colliding according to various shapes of the surface of the object, the direction induction nozzle 500 may induce and recover the particles P removed from the object M in a desired direction by injecting the direction induced gas toward the inlet of the recovery pipe 310.

In the gas injection part 600, a gas injection pipe 610 is connected to the other side of the casing 100, that is, an opposite side of the nozzle block 210, the gas injection pipe 610 is connected with the air compressor 260 to receive compressed gas, and an opening/closing valve 620 which is automatically controlled to be opened and closed by the control part 800, and an air filter 630 are provided. At this time, cleaning gas injected from the gas injection part 500 moves in a longitudinal direction inside the casing 100 along an outer side of the recovery pipe 310.

That is, when the gas with a predetermined pressure is injected toward the surface of the object M from the gas nozzles 220, some of gas around the gas nozzles 220 is swept out together to the central portion of the nozzle block 210. At this time, foreign materials which have existed around also move together to be introduced to the recovery pipe 310 and then mixed with the particles P removed from the object M, so that it may be difficult to accurately measure the particles during detection and counting by the particle detection part 700 connected with the recovery part 300.

As a result, when the cleaning gas is injected at a predetermined pressure along the inside of the casing 100, more particularly, the periphery of the recovery part 310 through the gas injection pipe 610, foreign substances other than the particles P are prevented from being introduced to the recovery part 300 and thus, it is possible to more accurately detect and count the particles P removed from the object M. At this time, the cleaning gas is injected in a direction opposite to the direction of the particles P introduced to the recovery part 300.

In the particle detection part 700, a suction port 710 is connected with the recovery pipe 310 of the recovery part 300 to suction the particles P moving on the recovery passage of the recovery pipe 310, thereby detecting or counting the particles. The number, the sizes, the distribution, etc. of the particles P are measured by detecting and the counting the particles P, thereby easily and rapidly checking the contamination and the degree thereof in the clean room and further preventing defects of products.

The control part 800 controls the opening/closing valve 240 of the gas injection part 200 to automatically control the injection time and the inject intervals of the gas. Further, the control part 800 also controls and open/closes the opening/closing valves 520 and 620 to control the injection time and the injection amounts of the direction induced gas and the cleaning gas injected to the direction induction nozzle 500 and the gas injection pipe 610.

When the gas is continuously injected from the gas nozzles 220, the injection amount is greatly increased, and as a result, there is a problem that the gas moves to a desired distance or more and the scale of the recovery part 300 needs to be increased by the distance. Accordingly, the control part 800 controls the opening/closing valve 240 according to a prestored setting so as to fit the scale of the recovery part 300 such as the size, a suction force, etc. of the recovery pipe 310, so that the gas is intermittently injected, thereby smoothly recovering and collecting the particles P. For example, if the recovery part 300 may recover a gas injection amount per 1 second of the gas nozzles 220 after 10 seconds, the control part 800 controls the opening/closing valve 240 to have a pause time of 10 seconds after the gas nozzles 220 inject the gas for 1 second.

In the present invention, the embodiment is one example and the present invention is not limited thereto. Anything that has substantially the same configuration as the technical idea described in the appended claims of the present invention and achieves the same operation and effect will be included in the technical scope of the present invention.

### INDUSTRIAL APPLICABILITY

Since the gas nozzles inject in symmetrical directions to prevent diffusion of particles removed from the surface of an object, the object is not contaminated, and the particles are able to be accurately recovered, detected and counted, the apparatus for removing the particles using the symmetrical gas injection according to the present invention has industrial applicability.

1. An apparatus for removing particles using symmetrical gas injection, the apparatus comprising:
a casing having an inner space;
a gas injection part in which a plurality of gas nozzles are formed on one side of the casing, the plurality of gas nozzles are disposed symmetrically and away from an object, and particles on the surface of the object are removed by injecting gas on the object;
a recovery part which has a recovery pipe connected to the other side of the casing and inserted therein and recovers the particles removed from the object to the recovery pipe; and
a direction induction nozzle which is formed in the casing to induce the particles removed from the object in a desired direction.

2. An apparatus for removing particles using symmetrical gas injection, the apparatus comprising:
a casing having an inner space;
a gas injection part in which a plurality of gas nozzles are formed on one side of the casing, the plurality of gas nozzles are disposed symmetrically and away from an object, and particles on the surface of the object are removed by injecting gas on the object;
a recovery part which has a recovery pipe connected to the other side of the casing and inserted therein and recovers the particles removed from the object to the recovery pipe; and
a gas injection part which is connected to the casing and injects cleaning gas to the inside to prevent foreign substances from being introduced to the recovery part.

3. An apparatus for removing particles using symmetrical gas injection, the apparatus comprising:
a casing having an inner space;
a gas injection part in which a plurality of gas nozzles are formed on one side of the casing, the plurality of gas nozzles are disposed symmetrically and away from an object, and particles on the surface of the object are removed by injecting gas on the object;
a recovery part which has a recovery pipe connected to the other side of the casing and inserted therein and recovers the particles removed from the object to the recovery pipe; and
a second recovery part which is formed on a back side of the object and suctions the particles removed from the object.

4. The apparatus of any one selected from claim 1, further comprising:
a particle detection part which is connected with the recovery pipe of the recovery part to detect and count the suctioned particles.

5. The apparatus of any one selected from claim 1, wherein a membrane filter is provided in the recovery pipe to be able to collect the particles.

6. The apparatus of any one selected from claim 1, further comprising:
a control part which controls an opening/closing valve of the gas injection part to automatically control the injection time and the injection intervals of the gas.

7. The apparatus of any one selected from claim 2, further comprising:
a particle detection part which is connected with the recovery pipe of the recovery part to detect and count the suctioned particles.

8. The apparatus of any one selected from claim 3, further comprising:
a particle detection part which is connected with the recovery pipe of the recovery part to detect and count the suctioned particles.

9. The apparatus of any one selected from claim 2, wherein a membrane filter is provided in the recovery pipe to be able to collect the particles.

10. The apparatus of any one selected from claim 3, wherein a membrane filter is provided in the recovery pipe to be able to collect the particles.

11. The apparatus of any one selected from claim 2, further comprising:
a control part which controls an opening/closing valve of the gas injection part to automatically control the injection time and the injection intervals of the gas.

12. The apparatus of any one selected from claim 3, further comprising:
a control part which controls an opening/closing valve of the gas injection part to automatically control the injection time and the injection intervals of the gas.
